(19) United States
(12) Patent Application Publication
(10) Pub. No.: US 2012/0043555 A1
(43) Pub. Date: Feb. 23, 2012

(54) LIQUID FLUORESCENT COMPOSITION AND LIGHT EMITTING DEVICE

(76) Inventors: Chi-Shen Tuan, Hsinchu City (TW); Wan-Jung Teng, Hsinchu County (TW); Mei-Ling Chou, Hsinchu City (TW); Yu Hsuan Wang, Changhua County (TW); Ching-Cheng Sun, Taoyuan County (TW); Tsung-Hsun Yang, Hsinchu City (TW)

(21) Appl. No.: 13/319,063

(22) PCT Filed: Mar. 19, 2010
(86) PCT No.: PCT/CN2010/000333

§ 371 Date: Nov. 4, 2011

(30) Foreign Application Priority Data
May 7, 2009 (CN) 200910136313.9

(51) Int. Cl. H01L 33/02; C09K 11/06; H01L 33/50

(52) U.S. Cl. 257/76; 257/98; 252/301.35; 257/E33.061; 257/E33.023

(57) ABSTRACT

The invention provides a liquid fluorescent composition. The liquid fluorescent composition includes at least (a) 0.001-2 parts by weight of a fluorescent material; and (b) 100 parts by weight of a cyclic solvent having a boiling point above 100° C. The invention also provides a light emitting device containing the above liquid fluorescent composition.

### CROSS REFERENCE TO RELATED APPLICATIONS

This application claims priority of China Patent Application No. 200910136313.9, filed on May 7, 2009, the entire contents of which are incorporated herein by reference.

### BACKGROUND OF THE INVENTION

1. Field of the Invention

The invention relates to a fluorescent agent, and more particularly to a fluorescent agent and applications thereof.

2. Description of the Related Art

In general, white light emitting diodes (LEDs) can be formed by using a blue light from a blue LED die to excite the YAG: Ce³⁺ fluorescent powder to luminesce a yellow light and then the yellow light is mixed with the unabsorbed blue light to form a white light. Additionally, white light emitting diodes (LEDs) can be formed by using a light from a UV LED die to excite the red, green and blue (RGB) fluorescent powders and then mix the red, green and blue lights produced from the fluorescent powders to form a white light.

For the conventional fabrication method of white light emitting diodes, the fluorescent powders need to be mixed with a high transparent, high temperature resistant bonding agent, and then the mixture is cured to complete the LED. However, the fluorescent powder is incompatible with the bonding agent such that it does not disperse uniformly in the bonding agent and results in non-uniform luminescence from the LED.

Prior art patents relating to the field of fluorescent agents includes Taiwan Patent No. 459403, Taiwan Patent No. 565956, U.S. Pub. No. 20040231554, and JP 2004-326910. The patents, however, disclosed solid fluorescent compositions in which mixing is needed with a non-saturated transparent resin and a bonding or an accelerant and then curing to form a solid fluorescent layer for LEDs.

### BRIEF SUMMARY OF THE INVENTION

The invention provides a liquid fluorescent composition, including:

(a) 0.001-2 parts by weight of a fluorescent material, wherein the fluorescent material includes a fluorescent polymer, a fluorescent dye, or combinations thereof; and

(b) 100 parts by weight of a cyclic solvent having a boiling point above 100° C.

Further, the liquid fluorescent composition can optionally include:

(c) 1-50 parts by weight of a color modifying agent, or preferably 3-40 parts by weight; and

(d) 0.02-5 parts by weight of a hindered amine light stabilizer (HALS), or preferably 0.5-2 parts by weight.

The invention further provides a light emitting device, including: a substrate; a light emitting element disposed on the substrate; the aforementioned liquid fluorescent composition disposed on the light emitting element; and a sealing element encapsulating the liquid fluorescent composition into a chamber.

It should be noted that the liquid fluorescent composition absorbs a light with a first wavelength emitted by the light-emitting element and converts the light with the first wavelength to a light with a second wavelength. Further, the light with a first wavelength and the light with a second wavelength are mixed to serve as a white light source.

A detailed description is given in the following embodiments with reference to the accompanying drawings.

### BRIEF DESCRIPTION OF THE DRAWINGS

The invention can be more fully understood by reading the subsequent detailed description and examples with reference to the accompanying drawings, wherein:

FIG. 1 shows a schematic cross section of a light emitting device according to an embodiment of the invention.

### DETAILED DESCRIPTION OF THE INVENTION

The following description is of the best-contemplated mode of carrying out the invention. The description is provided for illustrating the general principles of the invention and is not meant to be limiting. The scope of the invention is best determined by reference to the appended claims.

The invention provides a liquid fluorescent composition and associated applications for use. The liquid fluorescent composition is different from a solid fluorescent composition prepared by curing the mixture of a fluorescent agent and a bonding resin.

In the present invention, dissoluble fluorescent materials are dissolved into a cyclic solvent, obtaining a homogeneous liquid fluorescent composition. The excitation wavelength of the liquid fluorescent composition can be adjusted by the conjugated degree of the cyclic solvent for achieving optimally luminescent performance thereof.

Further, an optional color modifying agent can be added into the liquid fluorescent composition to modify the luminescent color and the viscosity of the liquid fluorescent composition. The liquid fluorescent composition can be formed on the light emitting element (such as blue LED chip) by various processes such as an ink-jet printing, screen printing, coating, casting, priming, or dispensing process, thereby constituting a fluorescent layer (the liquid fluorescent composition can be coated on the light emitting element to form a layer without curing). After encapsulating by a sealing element (such as a glass optical lens), a white source or a composite light source with a simple process can be provided.

The components and amounts of the liquid fluorescent composition are discussed in detail below.

The liquid fluorescent composition or the invention substantially includes:

(a) 0.001-2 parts by weight of a fluorescent material, or preferably 0.01-1 parts by weight; and

(b) 100 parts by weight of a cyclic solvent.

Further, the liquid fluorescent composition can optionally include:

(c) 1-50 parts by weight of a color modifying agent, or preferably 3-40 parts by weight; and

(d) 0.02-5 parts by weight of a hindered amine light stabilizer (HALS), or preferably 0.5-2 parts by weight.

The aforementioned (a) fluorescent material can include a fluorescent polymer, a fluorescent dye, or combinations thereof. The fluorescent polymer can be a fluorene derivative copolymer with modifiable luminescent color and high luminescent efficiency, such as compounds copolymerized by 9,9-Dialkyl-fluorene (as a core) and aromatic molecules with high fluorescence. The fluorescent polymer can be prepared by fluorene derivative monomer and at least one molecule with conjugated groups (such as a phenyl group, a naphthyl group, a heterocyclic group, a multi-ring aromatic group, or a multi-ring heterocyclic group), as shown in formula (I):

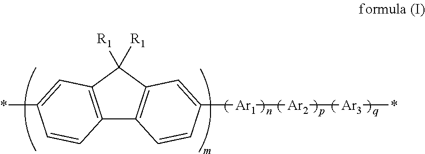

wherein Ar₁, Ar₂, and Ar₃ are each independently selected from:

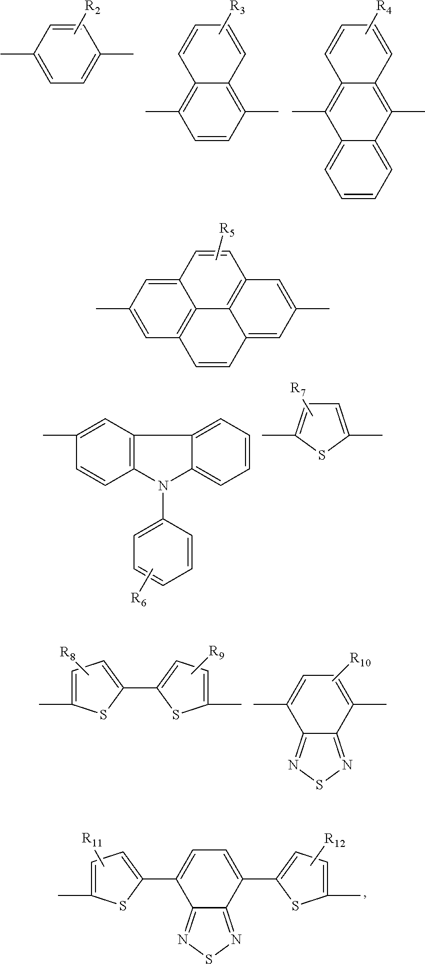

wherein, R₁-R₁₂ are each independently hydrogen, hydroxyl group, C₁-C₂₂ linear or branched alkyl group, C₁-C₂₂ linear or branched alkoxy group, ortho-, meta-, or para-alkyl phenyl, or ortho-, meta-, or para-alkoxy phenyl, m, n, p, q of formula (I) is the number of repeated units, and the ratio of m to m+n+p+q is at least more than 0.1, or preferably more than 0.5. In embodiments of the invention, one or two of n, p, and q can be zero.

Further, the fluorescent polymer can include a poly(p-phenylene vinylene) (PPV) polymer as shown in formula (III):

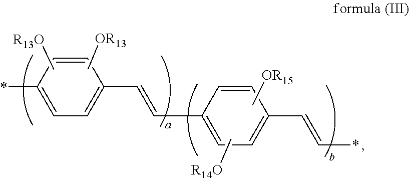

wherein, R₁₃-R₁₅ are each independently C₁-C₂₂ linear or branched alkyl group, ortho-, meta-, or para-alkyl phenyl, or ortho-, meta-, or para-alkoxy phenyl, and a, b of formula (III) is the number of repeated units. Depending on the desired luminescent color, one of a and b can be zero (such as DB-PPV with green luminescence). When the ratio of a to a+b is at least more than 0.5 (preferably more than 0.8), the fluorescent polymer has yellow luminescence.

In addition to the fluorescent polymer, the (a) fluorescent material can also be a fluorescent dye, such as coumarin 6, fluorescein, acridine, 4-(Dicyanomethylene)-2-methyl-6-[p-(dimethylamino)-styryl]-4H-pyran, nitrostilbene, nitrobenzoxadiazole, riboflavin, rhodamine, or combinations thereof.

In an embodiment, the (a) fluorescent material has an ultraviolet-visible (UV-Vis) absorption spectrum at 440-470 nm wavelength corresponding to the emission wavelength of blue LEDs. In other embodiments, the (a) fluorescent material can have an absorption spectrum at other wavelengths corresponding to various light sources.

In the invention, the (a) fluorescent material serves as a fluorescent emitter. When the (a) fluorescent material is dissolved in a (b) cyclic solvent, the conjugated structure of the (b) cyclic solvent can produce resonance with the conjugated moieties of the (a) fluorescent material, thereby reducing the energy gap. Therefore, the red-shift degree of luminescence can be controlled by adjusting the conjugated degree of the (b) cyclic solvent, resulting in the desired luminescent color.

It should be noted that the (b) cyclic solvent must have a boiling point above 100° C., including a non-conjugated solvent (such as methylcyclohexane, decahydronaphthalene, or combinations thereof), a partially conjugated solvent (such as cyclohexylbenzene, 1,2,3,4-tetrahydronaphthalene, anisole, phenetole, ethylbenzene, propylbenzene, cumene, or combinations thereof), or a fully conjugated solvent (such as toluene, xylene, tri-methyl benzene (TMB), methylnaphthalene, dimethylnaphthalene or combinations thereof). The structure and the characteristic of a part of cyclic solvents are listed in Table 1.

TABLE 1

| cyclic solvent | structure | bp(° C.) | n_{d} |
|---|---|---|---|
| non-conjugated solvent | 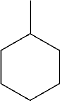 Methylcyclohexane | 101 | 1.422 |
| | 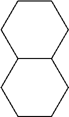 Decahydronaphthalene | 188 | 1.475 |
| partially conjugated solvent | 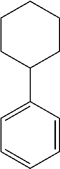 Cyclohexylbenzene | 239 | 1.526 |
| | 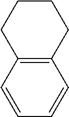 Tetrahydronaphthalene | 206 | 1.541 |
| | 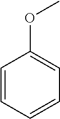 Anisole | 153.7 | 1.5174 |
| fully conjugated solvent | 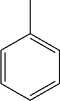 Toluene | 111 | 1.4967 |
| | 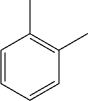 o-Xylene | 144 | 1.505 |
| | 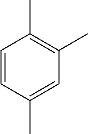 Tri-methyl benzene | 168 | 1.504 |
| | 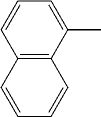 1-Methylnaphthalene | 242 | 1.615 |

Further, in the invention, a (c) color modifying agent can be optionally added into the liquid fluorescent composition. The (c) color modifying agent can have a cyclic molecule structure and be dissolved in the (b) cyclic solvent and include non-conjugated molecules, partially conjugated molecules, fully conjugated molecules, or combinations thereof. The non-conjugated color modifying agent can be cycloolefin copolymer (m-COC). The partially conjugated color modifying agent can be polystyrene (PS). The fully conjugated color modifying agent can be biphenylene, or naphthalene. The structure and the characteristic of some color modifying agents are listed in Table 2.

TABLE 2

| color | | | |
|---|---|---|---|
| modifying | | mp or | |
| agent | structure | Tg (° C.) | nd |
| non- conjugated molecules | 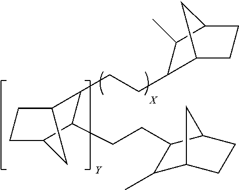 m-COC | Tg = 161.4 (Topas 6015) | 1.52 (Topas 6015) |
| partially conjugated molecules | 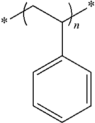 PS | Tg = 94 (80 G/CM) | 1.59 (80 G/CM) |
| fully conjugated molecules | 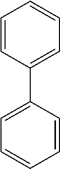 Biphenylene | mp = 70 | — |
| | 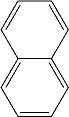 Naphthalene | mp = 81 | 1.582 |

The luminescent color of the liquid fluorescent composition can be modified by adjusting the conjugated degree of the color modifying agent, thereby precisely achieving the desired luminescent color such as 550 nm and enhancing the luminescent efficiency.

Further, the color modifying agent can be used to adjust the viscosity of the liquid fluorescent composition, facilitating the liquid fluorescent composition to form a layer by various processes. The viscosity of the liquid fluorescent composition can be of between 1 to 50,000 cps (at a temperature of 25° C.).

In general, in absence of the (c) color modifying agent, the liquid fluorescent composition having lower viscosity (1-20 cps at a temperature of 25° C.) is suitable to be formed into a layer by an ink-jet printing and priming process. After adding the (c) color modifying agent, the liquid fluorescent composition would have a medium viscosity (10-1000 cps at a temperature of 25° C.) suitable to be formed into a layer by a coating process, or a higher viscosity (500-50,000 cps at a temperature of 25° C.) suitable to be formed into a layer by a screen printing or dispensing process.

In an embodiment, the liquid fluorescent composition can absorb a light with a first wavelength (440-460 nm) emitted by a blue light source, and converts the light with a first wavelength to a light with a second wavelength (such as 530-700 nm). The light with a first wavelength and the light with a second wavelength can be mixed to serve as a white light source. Alternatively, the light with a first wavelength (440-460 nm) can convert completely to the light with a second wavelength (such as green lights, yellow lights, or red lights).

Moreover, the liquid fluorescent composition of the invention can include optionally a hindered amine light stabilizer (HALS) to improve the stability thereof. The hindered amine light stabilizer (HALS) can include bis(2,2,6,6-tetramethyl-4-piperidinyl) sebacate, n-methyl-1-butanamin, or combinations thereof.

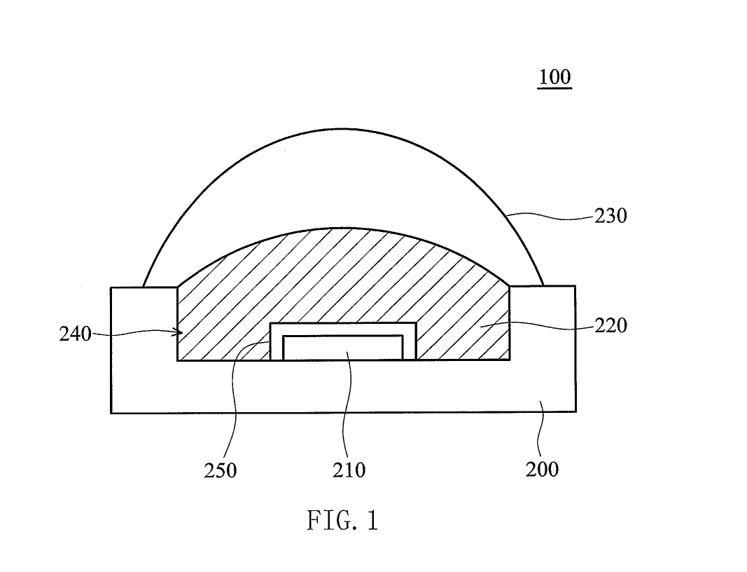

The following description with reference to FIG. 1 is intended to illustrate application of the liquid fluorescent composition as disclosed in the invention. FIG. 1 is a schematic diagram of a light emitting device 100 according to an embodiment of the invention. The light emitting device 100 includes a substrate 200 (such as a ceramic carrier) and a light emitting element 210 disposed on the substrate 200. The type of the light emitting element 210 can be (but is not limited to) an inorganic light-emitting diode, a laser diode, or an organic light-emitting diode. In an embodiment, the light emitting element 210 includes a blue light emitting chip of GaN or GaInN.

The liquid fluorescent composition 220 can be disposed on the light-emitting element 210 by an ink-jet printing, screen printing, coating, casting, priming, or dispensing process, serving as a fluorescence converting layer (without curing). A sealing element 230, such as a glass or plastic cap, is provided to encapsule the liquid fluorescent composition 220 into the chamber 240. The liquid fluorescent composition 220 can absorb a light with a first wavelength emitted by the light-emitting element 210 and convert the light with a first wavelength to a light with a second wavelength. Further, the light with a first wavelength and the light with a second wavelength can be mixed to serve as a white irradiance. Therefore, a white light source (or a composite light source) with high light efficiency can be provided.

Before forming the liquid fluorescent composition 220 on the light-emitting element 210, a transparent protection layer 250 can be formed on the light-emitting element 210, separating the light-emitting element 210 from the liquid fluorescent composition 220. Therefore, the performance of the light-emitting element 210 is adversely influenced by the direct contact of the liquid fluorescent composition 220. The transparent protection layer 250 can be epoxy resin, acrylic resin, or polyvinyl acetate resin and has a thickness of between 0.1-1.0 μm.

Referring to FIG. 1, the substrate 200 is a cup-shaped substrate and the liquid fluorescent composition 220 is encapsuled into the chamber 240, wherein the sealing element 230 and the substrate 200 together define the chamber 240. In other embodiments, the substrate 200 can be substrates having a cavity with various shapes or a planar substrate. Further, the sealing element 230 can be a transparent plate case, rather than a lens-shaped sealing element. When the sealing element is a transparent plate case, the liquid fluorescent composition is primed into the space of the transparent plate case. After sealing, packaging and combining with a blue-emission back light source, a planar light source can be provided.

In addition, various sized bubbles or incompatible transparent liquid can be disposed into the chamber to form floating and transparent circular bubble/vacuoles. After combining with a blue (or other color) back light, an artistic totem light source is provided. The viscosity of the incompatible transparent liquid can be different from that of the liquid fluorescent composition. Alternatively, the incompatible transparent liquid can be other liquid fluorescent compositions with different emission wavelengths.

Accordingly, The emission wavelength of the liquid fluorescent composition of the invention can be modified by adjusted the conjugated proportion of the (b) cyclic solvent and the (c) color modifying agent, resulting in the desired luminescent color and increased luminescent efficiency.

Since the liquid fluorescent composition can be used to form a layer by a single process without further curing, the method for forming a layer of the liquid fluorescent composition is simple. Since the liquid fluorescent composition is a homogeneous liquid mixture, the problem resulting from non-uniform distribution of fluorescent powder is eliminated. In an embodiment, a white light source having a luminous efficacy of 96 Lm/W and a correlated color temperature of 4358K (warm color) or having a luminous efficacy of 98 Lm/W and a correlated color temperature of 6452K (pure white) can be provided by combining the liquid fluorescent composition of the invention and a light emitting element. In some embodiments, the color rendering index (CRI) of the liquid fluorescent composition exceeds that of inorganic LED (such as Blue LED) incorporated with phosphor YAG (CRI=70), providing a light source having a color rendering index of about 84.

The preparation of components of the liquid fluorescent composition, the liquid fluorescent composition of the examples, and the related measurement results of the light emitting device employing the liquid fluorescent composition of the examples are described in detail as below:

### Prepared Example 1

### Synthesis of Monomer m1

### Monomer m1: 9,9-dioctyl-2,7-dibromofluorene

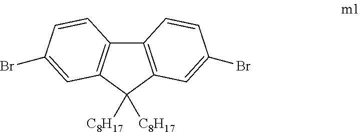

10 g of 2,7-dibromofluorene (Aldrich, 97%) was added into a reaction bottle. 175 ml of DMSO (ACROS), 8 g of potassium t-butoxide (Aldrich), and 19 g octylbromide (Aldrich) were added into the reaction bottle at a temperature of 45° C. After reaction for 24 hr, the result was diluted using ethyl acetate.

100 ml of water was used three times for extraction, and then the organic layers were combined, dried by magnesium sulfate, and concentrated, giving a white solid (15 g), and then purified by re-crystallization using an IPA (ACROS), giving acicular crystals of monomer m1 (13.25) with a yield of 77%. ¹H NMR (400 MHz, CDCl₃): δ (ppm) 7.51 (d, 2H), 7.45 (d, 2H), 7.44 (dd, 2H), 1.91 (t, 4H), 1.22-1.05 (m, 24H), 0.83 (t, 6H).

### Prepared Example 2

### Synthesis of Monomer m2

### Monomer m2: 9,10-Dibromoanthracene (CAS No. 523-27-3)

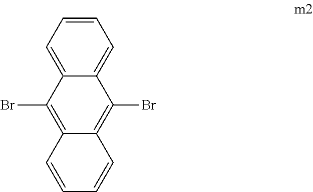

9,10-Dibromoanthracene, from Aldrich Co., was purified by re-crystallization.

### Prepared Example 3

### Synthesis of Monomer m3

### Monomer m3: 4,7-Dibromo-benzothiadiazole

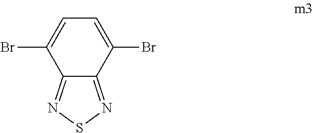

13.6 g of benzothiadiazole (CAS:273-13-2, Aldrich) was added into a reaction bottle and dissolved by 100 ml of dichloromethane (Merck). After stirring completely, 60 ml of HOAc (Merck) was added into the reaction bottle at room temperature. Next, 50 ml of acetic acid and 40 ml of bromine water (Br₂, Merck) were added dropwise into the reaction bottle. After an over night reaction period, the result was filtrated, and precipitate collected was washed by ether and then purified by re-crystallization using an IPA (ACROS), giving acicular crystals of monomer m3. ¹H NMR (400 MHz, CDCl₃):8 (ppm) 7.724 (s, 2H).

### Prepared Example 4

### Synthesis of Monomer m4

### Monomer m4: 4,7-Bis-(5-bromo-thiophen-2-yl-benzo[1,2,5]thiadiazole)

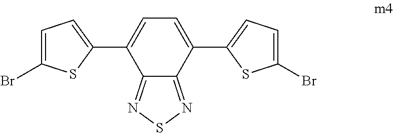

1 g of 4,7-dibromo-2,1,3-benzothiadiazole (monomer m3, 3.4 mmole), 3.06 g 2-(tributylstannyl) thiophene (8.2 mmole) and 0.0477 g Pd(PPh₃)₂Cl₂ (0.068 mmole) were added into a reaction bottle and dissolved by 25 ml of THF. After heating for reflux for 3 hours, the result was cooled down to terminate the reaction. After drying the THF, the result was purified by column separation, giving 0.71 g of a product of 4,7-dithien-2-yl-2,1,3-benzothiadiazole, with a yield rate of 69%.

3 grams of 4,7-dithien-2-yl-2,1,3-benzothiadiazole, 30 ml of CH₂Cl₂ (Aldrich) were stirred till dissolved, and a mixed solution of 20 ml of HOAc and 4 ml of Br₂ (Merck) were slowly added at a room temperature for reaction for 18 hours, and the precipitate was washed with water, and re-precipitated with CH₂Cl₂, giving a black red solid of monomer m4. ¹H NMR (400 MHz, CDCl₃): δ (ppm) 7.787 (d, 4H, 4.0 Hz), 7.140 (d, 2H, 4 Hz).

### Prepared Example 4

### Synthesis of Monomer m4

### Monomer m5: 1,4-Bisbromomethyl-2,3-dibutoxy benzene

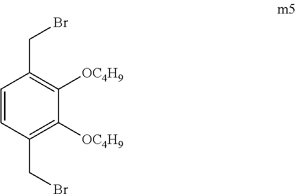

118.5 grams of Morpholine (Aldrich), 41 grams of formaldehyde (Merck), 500 ml of IPA (ACROS) were placed in a 1000 ml dual-neck vase, heated to 95° C., and added 50 grams of catechol (TCI), at a temperature of 95° C. for reaction for 2.5 hours. 100 ml of EA (ACROS) was added at room temperature, stirred for 30 minutes, and filtered, giving a solid, and added 300 ml of EA, heated to 60° C., stirred, cooled down, filtered, and washed with EA, giving 82 grams of a solid DBI, with a yield rate of 58.6%.

56.5 grams of DBI, 1000 ml of EtOH (99.5%, Merck), 100 g of K₂CO₃ (Aldrich), and 113 grams of n-butyl bromide (Aldrich) were added to a reaction bottle, heated to a reflux temperature for reaction for 69 hours, then filtered, concentrated, and dried. 500 ml of EA was added to the reaction bottle, extracted with water, dried with MgSO₄, filtered, and concentrated, giving 66.36 g of a brown liquid (DB2), with a yield rate of 86.1%.

66.36 g of DB2, 210 ml of CH3COOH (ACROS), 91 g of CH₃COONa (Aldrich), and 105 ml of acetic anhydride (Merck) were placed in a 1000 ml dual-neck bottle, heated to 103° C. for reaction for 89 hours, extracted with water and EA, dried with MgSO₄, filtered, and concentrated, giving 65.24 grams of a brown liquid (DB3). 200 ml of HBr (33% in glacial acetic acid, Aldrich) was added to the dual-neck bottle, and reacted at room temperature for 2.5 hours. The reaction solution was extracted with water and EA, dried with MgSO₄, filtered, and concentrated, giving 64.4 grams of a brown liquid, and then decolored by active carbon, and re-crystallized with methanol, giving a white solid of monomer m5. ¹H NMR (400 MHz, CDCl₃): δ (ppm) 7.082 (s, 2H), 4.519 (s, 4H), 4.086 (t, 4H, 6.7 Hz), 1.798 (m, 4H), 1.534 (m, 4H), 1.002 (t, 6H, 7.3 Hz).

The following reaction scheme illustrates the preparation of the monomer m5:

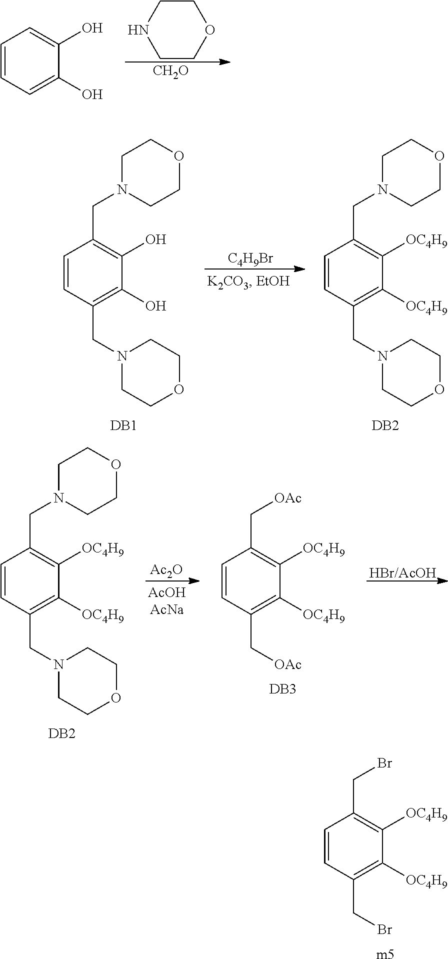

### Prepared Example 6

### Synthesis of Monomer m6

### Monomer m6: 2,5-Bis(bromomethyl)-1-methoxy-4-(2-ethylhexyloxy)benzene (CAS No. 2096255-56-2)

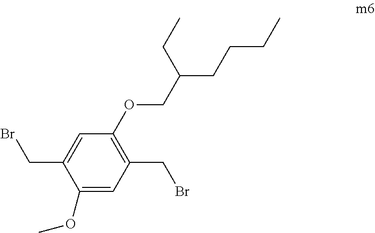

2,5-Bis(bromomethyl)-1-methoxy-4-(2-ethylhexyloxy)benzene, from Aldrich Co., was purified by re-crystallization.

### Prepared Example 7

### Synthesis of Fluorene Fluorescent Polymer

The green, yellow, and red fluorescent polymers were copolymerized through Yamamoto coupling reaction, using the monomer m1 as the major molecule combined with the monomers m3˜m4. The polymerization method for a yellow fluorene copolymer is described in detail below, wherein the other copolymers such as green and red fluorescent polymers are copolymerized by the same method.

Under de-gas water, 2.91 g of Bis(1,5-cyclooctadiene)Nickle, (10.59 mmole, Ni(COD)₂, Stream), 1.65 g 2,2-Bipyridyl (BPY, Aldrich), 1.3 ml cis,cis-1,5-Cyclooctadiene (10.59 mmole COD, Aldrich), and 5 ml anhydrous THF (Merk) were placed in a 50 ml reaction bottle, heated to 80° C., stirred for 30 minutes, and under nitrogen, the monomer dissolved in anhydrous and THF was added to the mixture.

The types and ratio of the monomers used was m1:m2:m3:m4=50 (2.75 g, 5 mmole):32.4 (0.96 g, 3.24 mmole):17.5 (0.58 g, 1.75 mmole):0.1 (0.04 g, 0.1 mole), and the mixture was reacted at a temperature of 80° C. for two days, and then 0.15 g of 4-tert-butylbenzyl bromide (0.7 mmole, Aldrich), and 10 ml of anhydrous THF were added for reaction for 24 hours. After the reaction was completed, the result was put into 1000 ml of THF, and 1 c.c. of HCl was added and stirred for 2 hours, filtered, and column separated to remove the metal catalyst. The resulting product was re-precipitated with methanol, washed by methanol, and vacuum dried to remove the remaining solvent, giving an orange solid of about 0.8 grams, with a yield rate of 40%. GPC:Mw=42K dalton, PDI=2.7. UV absorb peak (UV-Vis, film) was 434 nm, and PL peak was about 525 nm (excited at 450 nm wavelength).

The structure and the ratio between the repeated units (m, n, p, and q) of the obtained yellow, green and red fluorescent polymers are shown below:

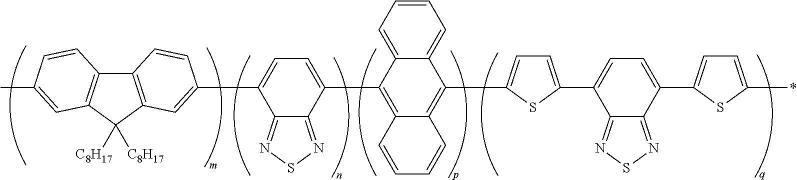

Red fluorescent polymer, m:n:p:q=50:17.5:30:2.5

Yellow fluorescent polymer, m:n:p:q=50:17.5:32.4:0.1

Green fluorescent polymer, m:n:p:q=50:17.5:32.5:0

### Prepared Example 8

### Synthesis of PPV Fluorescent Polymer

The green, yellow, and orange fluorescent polymers were copolymerized through Gilch dehydrohalogenation condensation polymerization, using the monomers m5 and m6 with different ratios to form green, yellow, and orange fluorescent polymers.

3 g of m5 monomer (7.4 mmole) and 0.158 g of m4 monomer (0.39 mmole) were placed in a tetra-neck vase, baked to dry, and under nitrogen, 300 ml of anhydrous THF was added, stirred until dissolved, giving a transparent colorless liquid. 60 ml of t-BuOK(Aldrich, conc.1M in THF) was added to the tetra-neck vase, giving a yellow solution, and under nitrogen, left at room temperature for reaction for 24 hours (Gilch dehydrohalogenation condensation polymerization), giving a yellow-green fluorescent dense liquid. The high viscous liquid was slowly put in a cup of MeOH, giving an orange gel, and filtered, and put in a vase to vacuum dry, giving an orange fiber-shaped solid. The orange fiber-shaped solid was dissolved in the THF again, and dripped slowly in a cup of MeOH, giving a gel, filtered, and put in a bottle to vacuum dry, giving an orange fiber-shaped solid of DB-MEH-PPV copolymer with a weight average molecular weight (Mw) of about 770 k Dalton, PDI=4.2. UV-Vis Absorb spectrum (film) of 467, 497 nm, and PL spectrum (film) of 556 nm (excited at 450 nm wavelength).

The structure of the obtained copolymer is shown below:

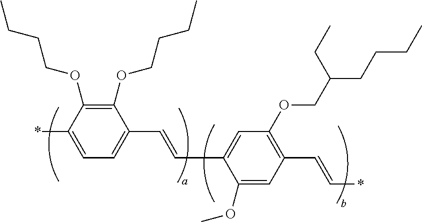

a and b are the number of repeated units.

DB-PPV and MEH-PPV as shown below were prepared by modifying the above steps:

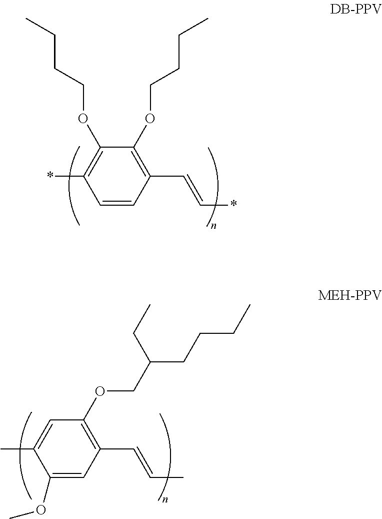

n is the number of repeated units.

### Example 1

### Yellow Fluorene Copolymer Liquid Fluorescent Composition

Liquid fluorescent compositions were prepared according to Table 3. The ultraviolet-visible (UV-Vis) absorption spectrum of the obtained liquid fluorescent compositions were respectively measured by a JASCO V-530 UV-Vis spectrophotometer, and the emission wavelength (PL) of the obtained liquid fluorescent compositions were respectively measured by an FL4500/Hitachi Fluorescence spectrophotometer (excited at 450 nm wavelength), and the results are shown in Table 3.

TABLE 3

| color modifying | fluorescent | cyclic | | |
|---|---|---|---|---|
| agent | material | solvent | | |
| (10 parts by | (0.05 parts by | (100 parts by | UV | PL |
| weight of) | weight of) | weight of) | (nm) | (nm) |
| cycloolefin | — | 1-methyl | — | — |
| copolymer | | naphthalene | | |
| cycloolefin | yellow | methyl- | 435 | 529.4 |
| copolymer | fluorescent | cyclohexane | | |
| | polymer of | | | |
| | Prepared | | | |
| | Example 7 | | | |
| cycloolefin | yellow | decahydro- | 437 | 535.0 |
| copolymer | fluorescent | naphthalene | | |
| | polymer of | | | |
| | Prepared | | | |
| | Example 7 | | | |
| cycloolefin | yellow | cyclohexane | 450 | 540.2 |
| copolymer | fluorescent | benzene | | |
| | polymer of | | | |
| | Prepared | | | |
| | Example 7 | | | |
| cycloolefin | yellow | 1-methyl | 451 | 543.0 |
| copolymer | fluorescent | naphthalene | | |
| | polymer of | | | |
| | Prepared | | | |
| | Example 7 | | | |
| polystyrene | yellow | trimethyl | 449 | 542.8 |
| | fluorescent | benzene | | |
| | polymer of | | | |
| | Prepared | | | |
| | Example 7 | | | |
| polystyrene | yellow | cyclohexane | 449 | 541.3 |
| | fluorescent | benzene | | |
| | polymer of | | | |
| | Prepared | | | |
| | Example 7 | | | |
| polystyrene | yellow | 1-methyl | 452 | 549.8 |
| | fluorescent | naphthalene | | |
| | polymer of | | | |
| | Prepared | | | |
| | Example 7 | | | |
| naphthalene | — | 1-methyl | — | — |
| | | naphthalene | | |
| naphthalene | yellow | methyl- | 446 | 537.6 |
| | fluorescent | cyclohexane | | |
| | polymer of | | | |
| | Prepared | | | |
| | Example 7 | | | |
| naphthalene | yellow | decahydro- | 450 | 537.6 |
| | fluorescent | naphthalene | | |
| | polymer of | | | |
| | Prepared | | | |
| | Example 7 | | | |
| naphthalene | yellow | cyclohexane | 449 | 541.8 |
| | fluorescent | benzene | | |
| | polymer of | | | |
| | Prepared | | | |
| | Example 7 | | | |
| naphthalene | yellow | 1-methyl | 456 | 552.8 |
| | fluorescent | naphthalene | | |
| | polymer of | | | |
| | Prepared | | | |
| | Example 7 | | | |
| — | yellow | 1-methyl | 453 | 553.6 |
| | fluorescent | naphthalene | | |
| | polymer of | | | |
| | Prepared | | | |
| | Example 7 | | | |

As shown in Table 3, the absorption wavelengths and emission wavelengths of the liquid fluorescent compositions including yellow fluorescent polymer can be modified by adjusting the proportion of the cyclic solvent and color modifying agent therein.

### Example 2

### Other Color Liquid Fluorescent Composition

Liquid fluorescent compositions were prepared according to Table 4. The ultraviolet-visible (UV-Vis) absorption spectrum of the obtained liquid fluorescent compositions were respectively measured by a JASCO V-530 UV-Vis spectrophotometer, and the emission wavelength (PL) of the obtained liquid fluorescent compositions were respectively measured by an FL4500/Hitachi Fluorescence spectrophotometer (excited at 450 nm wavelength), and the results are shown in Table 4.

TABLE 4

| color modifying | fluorescent | cyclic | | |
|---|---|---|---|---|
| agent | material | solvent | | |
| (10 parts by | (0.05 parts by | (100 parts by | UV | PL |
| weight of) | weight of) | weight of) | (nm) | (nm) |
| — | green | methyl- | 433 | 524 |
| | fluorescent | cyclohexane | | |
| | polymer of | | | |
| | Prepared | | | |
| | Example 7 | | | |
| polystyrene | green | toluene | 437 | 533.4 |
| | fluorescent | | | |
| | polymer of | | | |
| | Prepared | | | |
| | Example 7 | | | |
| — | green | 1-methyl | 455 | 543 |
| | fluorescent | naphthalene | | |
| | polymer of | | | |
| | Prepared | | | |
| | Example 7 | | | |
| — | red fluorescent | MeCHex | 438 | 529 |
| | polymer of | | | |
| | Prepared | | | |
| | Example 7 | | | |
| polystyrene | red fluorescent | toluene | 444 | 532.4, |
| | polymer of | | | 625.4 |
| | Prepared | | | |
| | Example 7 | | | |
| — | red fluorescent | 1-methyl | 455 | 625.4 |
| | polymer of | naphthalene | | |
| | Prepared | | | |
| | Example 7 | | | |
| | DB-PPV | toluene | 445 | 524 |
| — | DB-PPV | 1-methyl | 447 | 534.6 |
| | | naphthalene | | |
| | MEH-PPV | toluene | 495 | 572 |
| — | MEH-PPV | 1-methyl | 500 | 585 |
| | | naphthalene | | |
| — | coumarin-6 | THF | 460 | 490 |
| — | coumarin-6 | 1-methyl | 465 | 536 |
| | | naphthalene | | |

As shown in Table 4, the absorption wavelength and emission wavelength of the liquid fluorescent compositions including fluorescent polymer or fluorescent dye can be modified by adjusting the proportion of the cyclic solvent and color modifying agent therein.

### Example 3

### Fabrications of White, Green, and Red LEDs

0.02 parts by weight of yellow fluorescent polymer of Prepared Example 7, 0.5 parts by weight of green fluorescent polymer of Prepared Example 7, and 0.5 parts by weight of red fluorescent polymer of Prepared Example 7 were dissolved in 100 parts by weight of TMB. Next, 10 parts by weight of polystyrene (PS/80G Chimei) was added into the above mixture, giving a liquid fluorescent composition 1.

0.5 parts by weight of green fluorescent polymer of Prepared Example 7 was dissolved in 100 parts by weight of TMB. Next, 10 parts by weight of polystyrene (PS/80G Chimei) was added into the above mixture, giving a liquid fluorescent composition 2.

0.5 parts by weight of red fluorescent polymer of Prepared Example 7 was dissolved in 100 parts by weight of TMB. Next, 10 parts by weight of polystyrene (PS/80G Chimei) was added into the above mixture, giving a liquid fluorescent composition 3.

The liquid fluorescent compositions 1-3 were respectively coated on a Cree GaN blue LED chip with a protection layer of polyvinyl alcohol by a dispensing process. Next, the luminescent efficiency, correlated color temperature (CCT), and CIE color coordination of the obtained devices were measured by an integrating-sphere photometer under a current of 20 mA, and the results are shown in Table 5.

The liquid fluorescent compositions 1-3 were respectively dropped into a glass lens, and the glass lens was sealed with a Cree GaN blue LED chip. Next, the luminescent efficiency, correlated color temperature (CCT), and CIE color coordination of the obtained devices were measured by an integrating-sphere photometer under a current of 20 mA, and the results are shown in Table 5.

TABLE 5

| | | | | directly | encapsulating |
|---|---|---|---|---|---|
| | | | | formed on the | with glass |
| I (A) | V | CCT & CIE | lm | chip (lm/W) | lens (lm/W) |
| 0.02 | 2.716 | 4358K | 6.806 | 125.3 | 135 |
| | | (warm white) | | | |
| 0.02 | 2.714 | CIE = 0.36, | 9.2931 | 172 | 184 |
| | | 0.59 (Green) | | | |
| 0.02 | 2.716 | CIE = 0.56, | 1.037 | 19.1 | 20.6 |
| | | 0.32 (Red) | | | |

### Example 4

### White LEDs with Various CCTs

Yellow fluorescent polymer of Prepared Example 7, 0.5 parts by weight of green fluorescent polymer of Prepared Example 7, and 0.5 parts by weight of red fluorescent polymer of Prepared Example 7 were dissolved in 100 parts by weight of 1-methyl naphthalene, wherein the amount of the yellow fluorescent polymer of Prepared Example 7 was adjusted according to Table 6. Next, 10 parts by weight of naphthalene was added into the above mixture; giving a liquid fluorescent compositions.

The liquid fluorescent compositions were respectively dropped into a glass lens, and the glass lens was sealed with a Cree GaN blue LED chip. Next, the luminous flux, luminescent efficiency, correlated color temperature (CCT), and CIE color coordination of the obtained devices were measured by an integrating-sphere photometer under a current of 20 mA, and the results were shown in Table 6.

TABLE 6

| Yellow fluorescent | lumi- | lumines- | CIE color | | Excita- |
|---|---|---|---|---|---|
| polymer of Pre- | nous | cent ef- | coordi- | | tion wave- |
| pared Example 7 | flux | ficiency | nation | | length |
| (parts by weight) | (lm) | (lm/W) | (CIE x, y) | CCT | (nm) |
| 0.005 | 5.54 | 100.36 | 0.315, 0.41 | 9319 | 540 |
| 0.0063 | 6.19 | 112.14 | 0.312, 0.395 | 6201 | 540 |
| 0.0125 | 6.84 | 123.9 | 0.355, 0.48 | 5035 | 540 |
| 0.025 | 7.1 | 128.6 | 0.406, 0.564 | 4359 | 540 |
| 0.05 | 6.94 | 125.7 | 0.421, 0.563 | 4136 | 542 |

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

1.-25. (canceled)

26. A liquid fluorescent composition, comprising:
(a) 0.001-2 parts by weight of a fluorescent material, wherein the fluorescent material is as shown in formula (I): 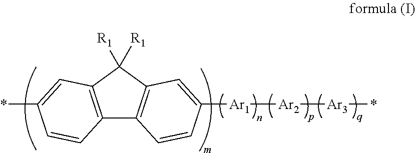
wherein Ar₁, Ar₂, and Ar₃ are each independently selected from: 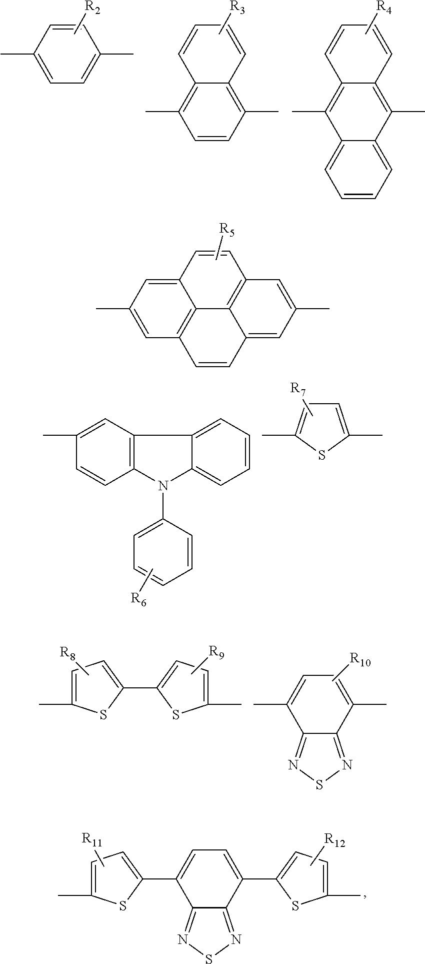
wherein, R₁-R₁₂ are each independently hydrogen, hydroxyl group, C₁-C₂₂ linear or branched alkyl group, C₁-C₂₂ linear or branched alkoxy group, ortho-, meta-, or para-alkyl phenyl, or ortho-, meta-, or para-alkoxy phenyl, m, n, p, q of formula (I) is the number of repeated units, and the ratio of m to m+n+p+q is at least more than 0.1; and
(b) 100 parts by weight of a cyclic solvent having a boiling point above 100° C.

27. The liquid fluorescent composition as claimed in claim 26, wherein the fluorescent dye comprises coumarin 6, fluorescein, acridine, 4-(Dicyanomethylene)-2-methyl-6-[p-(dimethylamino)-styryl]-4H-pyran, nitrostilbene, nitrobenzoxadiazole, riboflavin, rhodamine, or combinations thereof.

28. The liquid fluorescent composition as claimed in claim 26, wherein the fluorescent material has an ultraviolet-visible (UV-Vis) absorption spectrum at 440-470 nm wavelength.

29. The liquid fluorescent composition as claimed in claim 26, wherein the cyclic solvent comprises non-conjugated solvent, partially conjugated solvent, fully conjugated solvent, or combinations thereof.

30. The liquid fluorescent composition as claimed in claim 26, wherein the cyclic solvent comprises toluene, xylene, anisole, phenetole, tri-methyl benzene (TMB) ethylbenzene, propylbenzene, cumene, methylnaphthalene, dimethylnaphthalene, cyclohexylbenzene, methylcyclohexane, decahydronaphthalene, 1,2,3,4-Tetrahydronaphthalene, or combinations thereof.

31. The liquid fluorescent composition as claimed in claim 26, further comprising: (c) 1-50 parts by weight of a color modifying agent.

32. The liquid fluorescent composition as claimed in claim 31, wherein the color modifying agent having a cyclic molecule structure comprises non-conjugated molecules, partially conjugated molecules, fully conjugated molecules, or combinations thereof.

33. The liquid fluorescent composition as claimed in claim 31, wherein the color modifying agent comprises cycloolefin copolymer, polystyrene, biphenylene, naphthalene, or combinations thereof.

34. The liquid fluorescent composition as claimed in claim 26, wherein the liquid fluorescent composition has a viscosity at a temperature of 25° C. of 1-50,000 cps.

35. The liquid fluorescent composition as claimed in claim 26, wherein the liquid fluorescent composition has an emission wavelength of 530-700 nm.

36. The liquid fluorescent composition as claimed in claim 26, further comprising (d) 0.02-5 parts by weight of a hindered amine light stabilizer (HALS).

37. The liquid fluorescent composition as claimed in claim 26, wherein the hindered amine light stabilizer comprises bis(2,2,6,6-tetramethyl-4-piperidinyl) sebacate, n-methyl-1-butanamin, or combinations thereof.

38. A light emitting device, comprising:
a substrate;
a light emitting element disposed on the substrate;
the liquid fluorescent composition as claimed in claim 26 disposed on the light emitting element; and
a sealing element encapsulating the liquid fluorescent composition into a chamber.

39. The light emitting device as claimed in claim 38, wherein the light emitting element comprises an inorganic light emitting diode, a laser diode, or an organic light emitting diode.

40. The light emitting device as claimed in claim 38, wherein the light emitting element comprises blue light emitting chip of GaN or GaInN.

41. The light emitting device as claimed in claim 38, wherein the liquid fluorescent composition is disposed in the chamber by an ink-jet printing, screen printing, coating, casting, priming, or dispensing process.

42. The light emitting device as claimed in claim 38, wherein the liquid fluorescent composition absorbs a light with a first wavelength emitted by the light emitting element and converts the light with a first wavelength to a light with a second wavelength.

43. The light emitting device as claimed in claim 42, wherein the light with a first wavelength and the light with a second wavelength are mixed to serve as a white light source.

44. The light emitting device as claimed in claim 38, further comprising a protection layer disposed on the light emitting element, separating the light emitting element from the liquid fluorescent composition.

45. The light emitting device as claimed in claim 38, wherein the sealing element comprises a glass or plastic cap, and the sealing element and the substrate together define a chamber.

46. The light emitting device as claimed in claim 38, wherein the sealing element comprises a transparent plate case, and the chamber is within the transparent plate case.

47. The light emitting device as claimed in claim 38, further comprising a bubble within the chamber.

48. The light emitting device as claimed in claim 38, further comprising a transparent liquid within the chamber, wherein the transparent liquid and the liquid fluorescent composition are immiscible, and the transparent liquid and the liquid fluorescent composition have different viscosities.

49. The light emitting device as claimed in claim 38, wherein a plurality of the liquid fluorescent compositions are disposed in the chamber, and the plurality of the liquid fluorescent compositions have different emission wavelengths.

50. A liquid fluorescent composition, comprising:
(a) 0.001-2 parts by weight of a fluorescent material, wherein the fluorescent material comprises a poly(p-phenylene vinylene) (PPV) polymer as shown in formula (III): 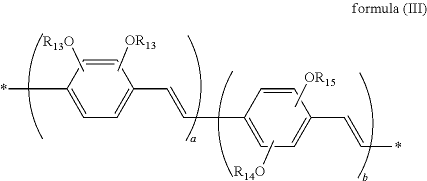
wherein, R₁₃-R₁₅ are each independently C₁-C₂₂ linear or branched alkyl group, ortho-, meta-, or para-alkyl phenyl, or ortho-, meta-, or para-alkoxy phenyl, and a, b of formula (III) is the number of repeated units; and
(b) 100 parts by weight of a cyclic solvent having a boiling point above 100° C.
